(19) United States
(12) Patent Application Publication
(10) Pub. No.: US 2024/0268117 A1
(43) Pub. Date: Aug. 8, 2024

(54) SEMICONDUCTOR DEVICE AND METHOD FOR MANUFACTURING SAME

(71) Applicant: Kioxia Corporation, Tokyo (JP)

(72) Inventors: Mitsuo IKEDA, Yokkaichi Mie (JP); Daisuke IKENO, Inuyama Aichi (JP); Ryosuke UMINO, Okazaki Aichi (JP)

(73) Assignee: Kioxia Corporation, Tokyo (JP)

(21) Appl. No.: 18/431,532

(22) Filed: Feb. 2, 2024

(30) Foreign Application Priority Data
Feb. 7, 2023 (JP) 2023-016944

(51) Int. Cl. H10B 43/27; H10B 41/27; H10B 41/30; H10B 43/30

(52) U.S. Cl. CPC H10B 43/27; H10B 41/27; H10B 41/30; H10B 43/30

(57) ABSTRACT

A semiconductor device includes: a film stack including a plurality of electrode layers and a plurality of first insulating films alternately stacked on top of one another; a charge storage layer provided between a side face of the electrode layers through a second insulating film; and a semiconductor layer provided between a side face of the charge storage layer through a third insulating film. At least one of the plurality of electrode layers includes a first layer and a second layer. The first layer is a polycrystalline layer including tungsten and nitrogen. The second layer is an amorphous layer including tungsten.

### CROSS-REFERENCE TO RELATED APPLICATION(S)

This application is based upon and claims the benefit of priority from Japanese Patent Application No. 2023-016944, filed Feb. 7, 2023, the entire contents of which are incorporated herein by reference.

### FIELD

Embodiments described herein relate generally to a semiconductor device and a method for manufacturing the same.

### BACKGROUND

For a three-dimensional semiconductor memory provided with an electrode layer such as a word line, reduction in electric resistance of the electrode layer, prevention of damage to a block insulating film due to the electrode layer, and prevention of increase in leak current due to the electrode layer are desirable.

### DESCRIPTION OF THE DRAWINGS

FIG. 1 is a perspective view illustrating a structure of a semiconductor device according to a first embodiment.

FIG. 2 is a cross-sectional view (1/4) illustrating a method for manufacturing the semiconductor device according to the first embodiment.

FIG. 3 is a cross-sectional view (2/4) illustrating the method for manufacturing the semiconductor device according to the first embodiment.

FIG. 4 is a cross-sectional view (3/4) illustrating the method for manufacturing the semiconductor device according to the first embodiment.

FIG. 5 is a cross-sectional view (4/4) illustrating the method for manufacturing the semiconductor device according to the first embodiment.

FIGS. 6A and 6B are cross-sectional views illustrating a structure of a semiconductor device according to a first comparative example of the first embodiment and a structure of the semiconductor device according to the first embodiment.

FIGS. 7A and 7B are cross-sectional views illustrating one example of the semiconductor device according to the first comparative example of the first embodiment and one example of the semiconductor device according to the first embodiment.

FIGS. 8A and 8B are cross-sectional views illustrating another example of the semiconductor device according to the first embodiment.

FIGS. 9A to 9D are diagrams illustrating a grain diameter of each crystal grain in a metal layer of the first embodiment.

FIGS. 10A to 10C are cross-sectional views illustrating the details of the method for manufacturing the semiconductor device according to the first embodiment.

FIGS. 11A to 11E are cross-sectional views illustrating the details of a method for forming an electrode layer of the first embodiment.

FIGS. 12A to 12C are graphs relating to characteristics of the semiconductor device according to the first embodiment.

FIGS. 13A to 13C are cross-sectional views illustrating structures of a semiconductor device according to a second comparative example of the first embodiment.

FIGS. 14A to 14C are cross-sectional views illustrating structures of the semiconductor device according to the first embodiment.

### DETAILED DESCRIPTION

In general, according to one embodiment, provided are a semiconductor device capable of forming an electrode layer having preferable characteristics and a method for manufacturing the semiconductor device.

According to one embodiment, a semiconductor device includes: a film stack including a plurality of electrode layers and a plurality of first insulating films alternately stacked on top of one another; a charge storage layer provided between a side face of the electrode layers through a second insulating film; and a semiconductor layer provided between a side face of the charge storage layer through a third insulating film. At least one of the plurality of electrode layers includes a first layer and a second layer. The first layer is a polycrystalline layer including tungsten and nitrogen. The second layer is an amorphous layer including tungsten.

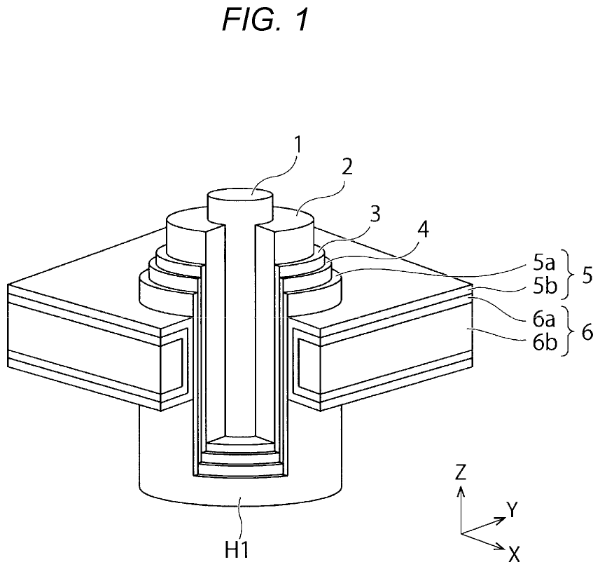

Embodiments will now be described with reference to the drawings. In FIGS. 1 to 14C, the same components are denoted by the same reference signs, and redundant description will be omitted.

### First Embodiment

FIG. 1 is a perspective view illustrating a structure of a semiconductor device according to a first embodiment. The semiconductor device according to the present embodiment includes, for example, a three-dimensional semiconductor memory.

The semiconductor device according to the present embodiment includes a core insulating film 1, a channel semiconductor layer 2, a tunnel insulating film 3, a charge storage layer 4, a block insulating film 5, and an electrode layer 6. The block insulating film 5 includes an insulating film 5a and an insulating film 5b. The electrode layer 6 includes a barrier metal layer 6a and an electrode material layer 6b. The tunnel insulating film 3 is an example of the third insulating film. The insulating film 5a is an example of the second insulating film.

In FIG. 1, multiple electrode layers and multiple insulating films are alternately stacked above a substrate, and a memory hole H1 is provided in these electrode layers and insulating films. FIG. 1 illustrates one electrode layer 6 of these electrode layers. These electrode layers function as a word line of the three-dimensional semiconductor memory, for example. FIG. 1 shows an X direction and a Y direction that are parallel to a surface of the substrate and perpendicular to each other, and a Z direction perpendicular to the surface of the substrate. In the present specification, a +Z direction is taken as an upward direction, and a −Z direction is taken as a downward direction. The −Z direction may coincide with the direction of gravity or may not coincide with the direction of gravity.

The core insulating film 1, the channel semiconductor layer 2, the tunnel insulating film 3, the charge storage layer 4, and the insulating film 5a are formed inside the memory hole H1 to constitute a memory cell of the three-dimensional semiconductor memory. The insulating film 5a is formed at a side face of the electrode layers and the insulating films in the memory hole H1, and the charge storage layer 4 is formed at a side face of the insulating film 5a. The charge storage layer 4 can store signal charges of the three-dimensional semiconductor memory. The tunnel insulating film 3 is formed at a side face of the charge storage layer 4, and the channel semiconductor layer 2 is formed at a side face of the tunnel insulating film 3. The channel semiconductor layer 2 functions as a channel of the three-dimensional semiconductor memory. The core insulating film 1 is formed at a side face of the channel semiconductor layer 2.

The insulating film 5a is, for example, a silicon oxide film (SiO₂ film). The charge storage layer 4 is, for example, a silicon nitride film (SiN film). The tunnel insulating film 3 is, for example, a SiO₂ film. The channel semiconductor layer 2 is, for example, a polysilicon layer. The core insulating film 1 is, for example, a SiO₂ film.

The insulating film 5b, the barrier metal layer 6a, and the electrode material layer 6b are formed between two insulating films among the multiple insulating films and are formed in sequence at a bottom face of an upper insulating film, a top face of a lower insulating film, and a side face of the insulating film 5a. The multiple insulating films are an example of the first insulating film. The barrier metal layer 6a is an example of the first layer. The electrode material layer 6b is an example of a second layer and a third layer.

The insulating film 5b is, for example, an aluminum oxide film (Al₂O₃ film). The barrier metal layer 6a is, for example, a tungsten nitride film (WN film). The electrode material layer 6b is, for example, a tungsten (W) layer. Further details of the barrier metal layer 6a and the electrode material layer 6b will be described later.

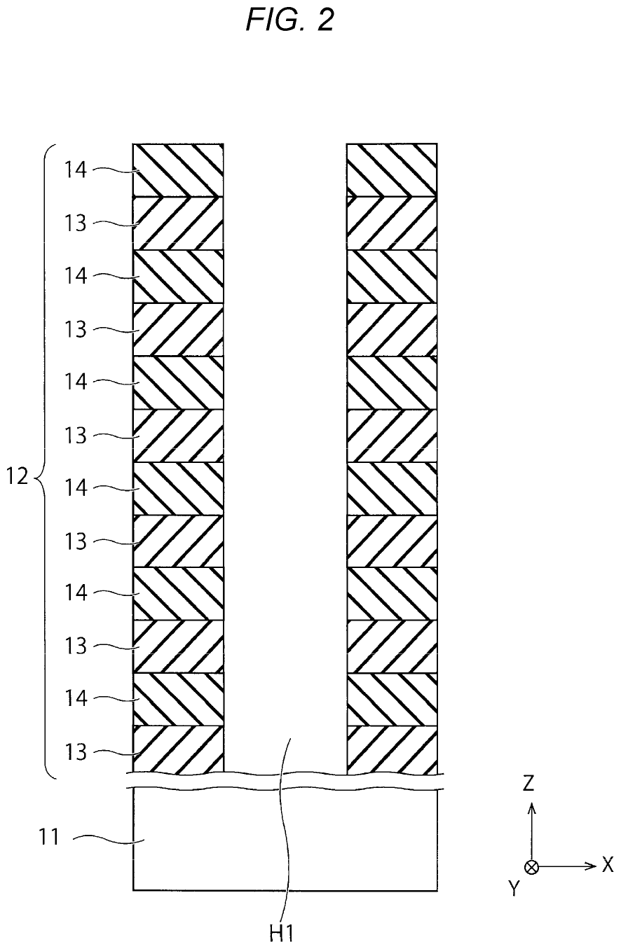

FIGS. 2 to 5 are cross-sectional views illustrating a method for manufacturing the semiconductor device according to the first embodiment.

First, a substrate 11 is prepared, and a film stack 12 alternately including multiple sacrificial layers 13 and multiple insulating layers 14 is formed above the substrate 11 (FIG. 2). The film stack 12 is formed by alternately stacking the multiple sacrificial layers 13 and the multiple insulating films 14 above the substrate 11. The film stack 12 may be formed directly on the substrate 11 or may be formed above the substrate 11 via another layer. The substrate 11 is, for example, a semiconductor substrate such as a silicon (Si) substrate. The sacrificial layer 13 is, for example, a SiN film. The insulating film 14 is, for example, a SiO₂ film. The sacrificial layer 13 is an example of a fifth layer, and the insulating film 14 is an example of the first insulating film.

Multiple memory holes H1 are subsequently formed in the film stack 12 by photolithography and reactive ion etching (RIE) (FIG. 2). FIG. 2 illustrates one of these memory holes H1. Each memory hole H1 of the present embodiment has a circular shape in a plan view and penetrates the film stack 12.

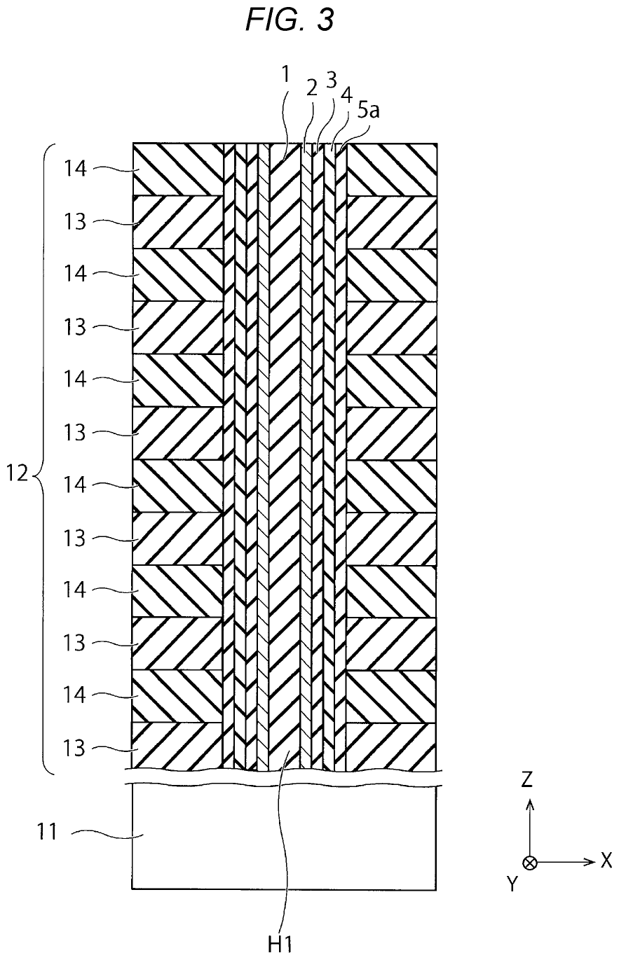

The insulating film 5a, the charge storage layer 4, the tunnel insulating film 3, the channel semiconductor layer 2, and the core insulating film 1 are subsequently formed, in sequence, at a side face of the film stack 12 in each memory hole H1 (FIG. 3). The insulating film 5a, the charge storage layer 4, the tunnel insulating film 3, and the channel semiconductor layer 2 are formed so as to have a tubular shape extending in the Z direction. The core insulating film 1 is formed so as to have a columnar shape extending in the Z direction.

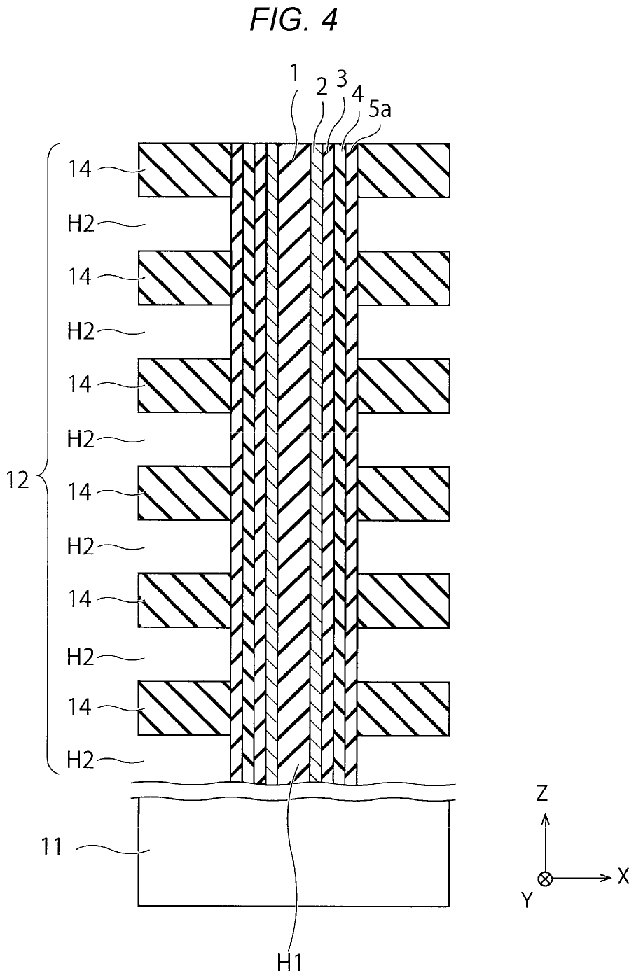

Multiple slits (not shown) are subsequently formed in the film stack 12, and the sacrificial layers 13 are removed, from the slits, with a chemical solution such as an aqueous solution of phosphoric acid. As a result, multiple recesses H2 are formed in the film stack 12 (FIG. 4). The recesses H2 are an example of first recesses.

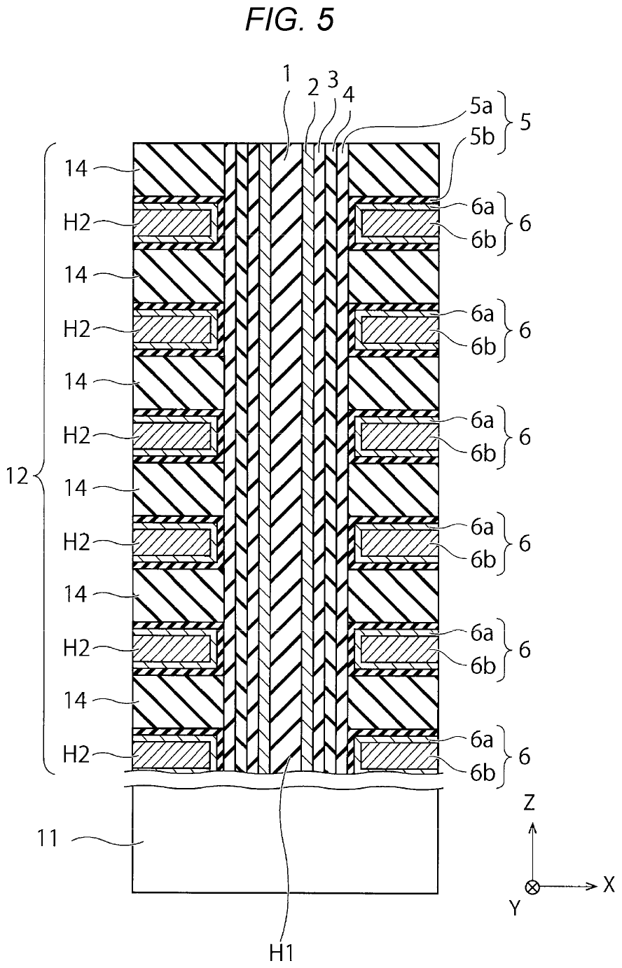

The insulating film 5b, the barrier metal layer 6a, and the electrode material layer 6b are subsequently formed in sequence at a surface of the insulating films 5a, 14 in each recess H2 (FIG. 5). Consequently, the block insulating film 5 including the insulating films 5a, 5b is formed. Furthermore, the electrode layer 6 including the barrier metal layer 6a and the electrode material layer 6b is formed in each recess H2. Furthermore, the film stack 12 alternately including multiple electrode layers 6 and multiple insulating films 14 is formed above the substrate 11. In this manner, a replacing step of replacing the sacrificial layers 13 with electrode layers 6.

Each recess H2 is formed between two insulating films 14 adjacent to each other in the Z direction. In each recess H2, the insulating film 5b, the barrier metal layer 6a, and the electrode material layer 6b are formed in sequence at a bottom face of an upper insulating film 14, a top face of a lower insulating film 14, and a side face of the insulating film 5a. Consequently, each electrode layer 6 is formed between insulating films 14 via the insulating film 5b.

In this manner, the semiconductor device according to the present embodiment is manufactured (FIG. 5). FIG. 1 illustrates part of the semiconductor device illustrated in FIG. 5.

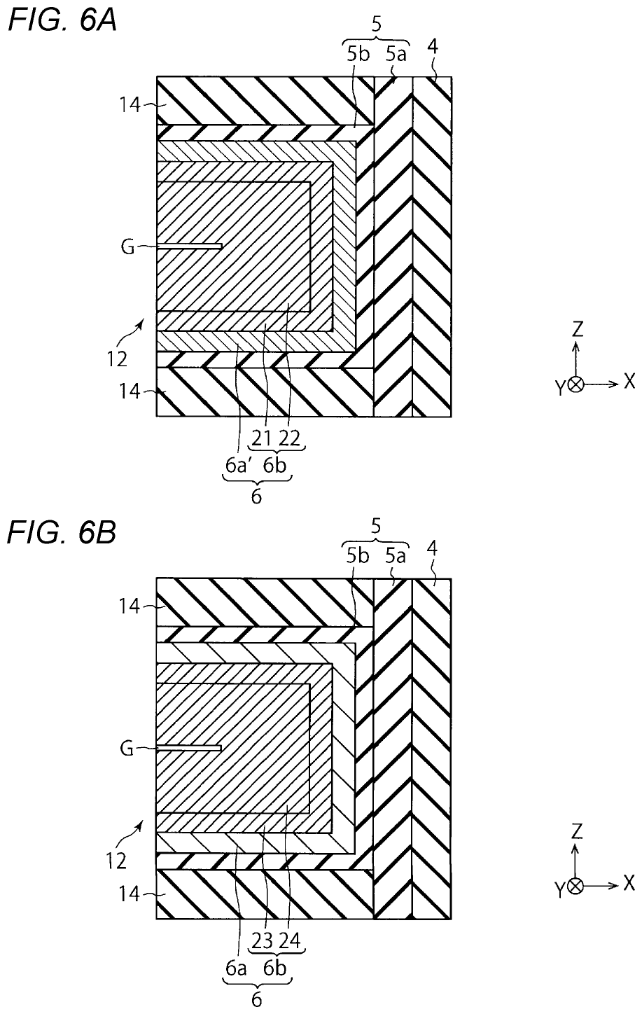

Next, the first embodiment and a first comparative example thereof will be compared with reference to FIGS. 6A to 8B.

FIGS. 6A and 6B are cross-sectional views illustrating a structure of a semiconductor device according to a first comparative example of the first embodiment and a structure of the semiconductor device according to the first embodiment.

FIG. 6A illustrates a structure of the semiconductor device according to the first comparative example. FIG. 6A illustrates a charge storage layer 4, a block insulating film 5, an electrode layer 6, an insulating film 14, and the like, similar to FIG. 5. Provided that the electrode layer 6 of the present comparative example includes a barrier metal layer 6a′ instead of the barrier metal layer 6a. FIG. 6A further illustrates an electrode material layer 6b of the electrode layer 6 and an air gap G in the electrode material layer 6b. As illustrated in FIG. 6A, the electrode material layer 6b of the present comparative example includes metal layers 21, 22 formed in sequence at a side face, a top face, and a bottom face of the barrier metal layer 6a′.

The barrier metal layer 6a′ is a titanium nitride film (TiN film). The metal layer 21 is a W layer. The metal layer 22 is a W layer. In the present comparative example, the barrier metal layer 6′a and the metal layer 22 are polycrystalline layers, and the metal layer 21 is an amorphous layer. Accordingly, the resistivity of the metal layer 22 is lower than the resistivity of the metal layer 21.

FIG. 6B illustrates a structure of the semiconductor of the first embodiment, similar to FIG. 5. While the electrode layer 6 of the above comparative example includes the barrier metal layer 6a′, the electrode layer 6 of the present embodiment includes the barrier metal layer 6a. FIG. 6B further illustrates the electrode material layer 6b of the electrode layer 6 and an air gap G in the electrode material layer 6b. As illustrated in FIG. 6B, the electrode material layer 6b of the present embodiment includes metal layers 23, 24 formed in sequence at a side face, a top face, and a bottom face of the barrier metal layer 6a. The metal layer 23 is provided between the barrier metal layer 6a and the metal layer 24. The barrier metal layer 6a is an example of the first layer, the metal layer 23 is an example of the second layer, and the metal layer 24 is an example of the third layer.

The barrier metal layer 6a is, for example, a WN film. The metal layer 23 is, for example, a W film. The metal layer 24 is, for example, a W film. In the present embodiment, the barrier metal layer 6a and the metal layer 24 are polycrystalline layers, and the metal layer 23 is an amorphous layer. Accordingly, the resistivity of the metal layer 24 is lower than the resistivity of the metal layer 23.

According to the present embodiment, the metal layer 23 can be made thinner than the metal layer 21 by forming the electrode layer 6 from a WN film (barrier metal layer 6a) instead of a TiN film (barrier metal layer 6a′). Consequently, electric resistance of the electrode layer 6 can be reduced by thinning the metal layer 23, which is a high-resistivity layer.

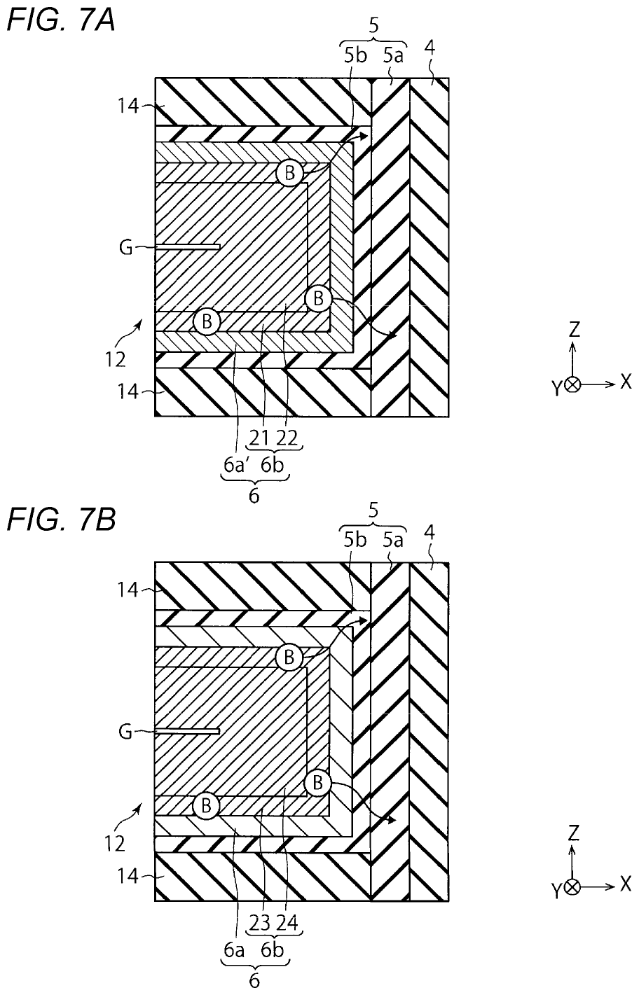

FIGS. 7A and 7B are cross-sectional views illustrating one example of the semiconductor device according to the first comparative example of the first embodiment and one example of the semiconductor device according to the first embodiment.

FIG. 7A illustrates an example of the semiconductor device according to the first comparative example. FIG. 7A illustrates a structure similar to FIG. 6A and further illustrates boron (B) atoms in the metal layer 21.

The metal layer 21 is a W layer formed using WF₆ gas and B₂H₆ gas in the example illustrated in FIG. 7A (W represents tungsten, F represents fluorine, B represents boron, and H represents hydrogen). Accordingly, the metal layer 21 includes B atoms as impurity atoms. When B atoms in the metal layer 21 diffuse into the block insulating film 5, erasing characteristics of the memory cell may deteriorate, and leak current may increase in the memory cell. Meanwhile, the metal layer 22 is a W layer formed using WF₆ gas and H₂ gas.

In the present comparative example, the barrier metal layer 6′a and the metal layer 22 are polycrystalline layers, and the metal layer 21 is an amorphous layer. When the metal layer 21 is formed using WF₆ gas and B₂H₆ gas, the metal layer 21 can be formed as an amorphous layer. In this case, when the metal layer 22 is formed at a surface of the barrier metal layer 6a′ via the metal layer 21, crystallinity of the barrier metal layer 6a′ hardly affects crystallinity of the metal layer 22 by action of the metal layer 21. Consequently, the grain diameter of crystal grains in the metal layer 22 can be increased even when the grain diameter of crystal grains in the barrier metal layer 6a′ is small. As a result, electric resistance of the metal layer 22 (electrode layer 6) can be reduced. However, in the example illustrated in FIG. 7A, a problem of diffusion of B atoms in the metal layer 21 arises, as described above.

FIG. 7B illustrates an example of the semiconductor device according to the first embodiment. FIG. 7B illustrates a structure similar to FIG. 6B and further illustrates boron (B) atoms in the metal layer 23.

The metal layer 23 is a W layer formed using WF₆ gas and B₂H₆ gas in the example illustrated in FIG. 7B as in the example illustrated in FIG. 7A. Therefore, the metal layer 23 includes B atoms as impurity atoms. When B atoms in the metal layer 23 diffuse into the block insulating film 5, erasing characteristics of the memory cell may deteriorate, and leak current may increase in the memory cell. Meanwhile, the metal layer 24 is a W layer formed using WF₆ gas and H₂ gas.

In the present embodiment, the barrier metal layer 6a and the metal layer 24 are polycrystalline layers, and the metal layer 23 is an amorphous layer. When the metal layer 23 is formed using WF₆ gas and B₂H₆ gas, the metal layer 23 can be formed as an amorphous layer. In this case, when the metal layer 24 is formed at a surface of the barrier metal layer 6a via the metal layer 23, crystallinity of the barrier metal layer 6a hardly affects crystallinity of the metal layer 24 by action of the metal layer 23. Consequently, the grain diameter of crystal grains in the metal layer 24 can be increased even when the grain diameter of crystal grains in the barrier metal layer 6a is small. As a result, electric resistance of the metal layer 24 (electrode layer 6) can be reduced. Furthermore, when the electrode layer 6 is formed from a WN film (barrier metal layer 6a) instead of a TiN film (barrier metal layer 6a′), electric resistance of the metal layer 23 (electrode layer 6) can be reduced. However, a problem of diffusion of B atoms in the metal layer 23 arises, as described above, also in the example illustrated in FIG. 7B.

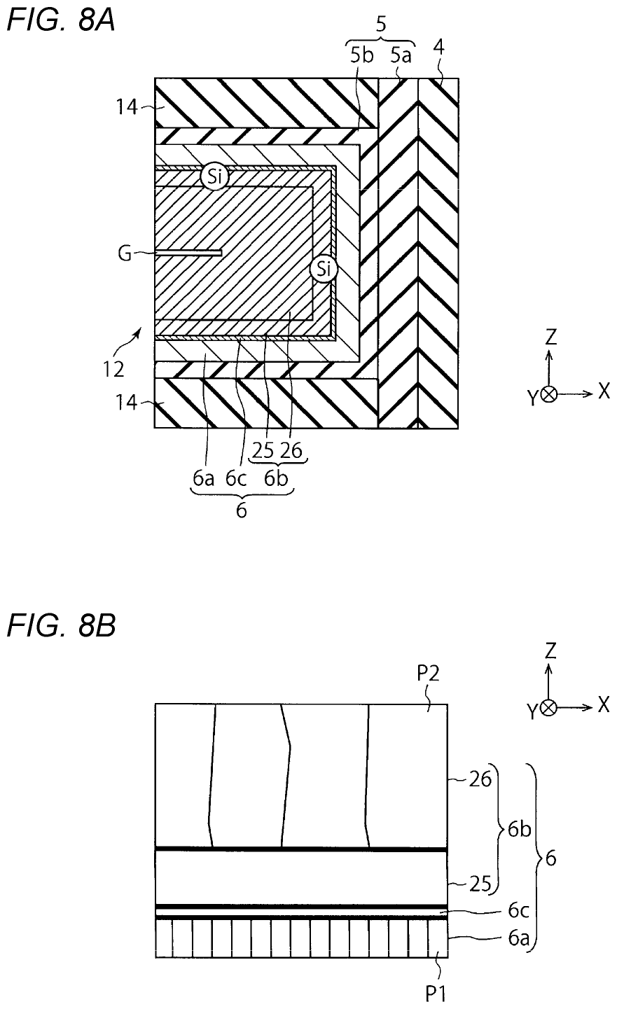

FIGS. 8A and 8B are cross-sectional views illustrating another example of the semiconductor device according to the first embodiment.

The electrode layer 6 includes a barrier metal layer 6a in the example illustrated in FIG. 8A as in the example illustrated in FIG. 7B. FIG. 8A also illustrates an electrode material layer 6b of the electrode layer 6 and an air gap G in the electrode material layer 6b. In the example illustrated in FIG. 8A, the electrode material layer 6b includes metal layers 25, 26 formed in sequence at a side face, a top face, and a bottom face of the barrier metal layer 6a. The metal layer 25 is provided between the barrier metal layer 6a and the metal layer 26. The metal layer 25 is also an example of the second layer similar to the metal layer 23. The metal layer 26 is also an example of the third layer similar to the metal layer 24.

The barrier metal layer 6a is, for example, a WN film as described above. The metal layer 25 is, for example, a W layer. The metal layer 26 is, for example, a W layer. In the example illustrated in FIG. 8A, the barrier metal layer 6a and the metal layer 26 are polycrystalline layers, and the metal layer 25 is an amorphous layer. Accordingly, the resistivity of the metal layer 26 is lower than the resistivity of the metal layer 25. FIG. 8A also illustrates silicon (Si) atoms in the metal layer 25.

The metal layer 25 is a W layer formed using a material gas including W and a halogen element and a reducing gas including Si and H in the example illustrated in FIG. 8A. The material gas is, for example, WF₆ gas. The reducing gas is, for example, SiH₄ gas or Si₂H₆ gas. Thus, the metal layer 25 includes Si atoms as impurity atoms instead of B atoms. Consequently, the problem associated with diffusion of B atoms can be prevented. The metal layer 25 is formed at, for example, 300° C. or lower and preferably 200° C. or lower.

It is noted that the metal layer 25 may include B atoms at a concentration low enough that the problem associated with diffusion of B atoms does not become serious. For example, the metal layer 25 may include B atoms diffusing from another layer. In the example illustrated in FIG. 8A, the B concentration in the metal layer 25 is lower than the Si concentration in the metal layer 25, both in the case where the metal layer 25 includes no B atom and in the case where the metal layer 25 includes B atoms at a low concentration. The Si concentration in the metal layer 25 is 6.0×10²¹ to 1.5×10²² atoms/cm³, for example. The Si concentration in the metal layer 25 changes according to the temperature at which the metal layer 25 is formed, for example. When the number of W atoms in the metal layer 25 is denoted as N1, and the number of Si atoms in the metal layer 25 is denoted as N2, the compositional ratio of Si atoms N2/(N1+N2) in the metal layer 25 becomes 0.10 to 0.15 (10% to 15%), for example.

The metal layer 26 is a W layer formed using WF₆ gas and H₂ gas similar to the metal layer 24. The metal layer 26 is a W layer formed using WF₆ gas as a material gas and H₂ gas as a reducing gas, for example. The metal layer 26 is formed, after forming the metal layer 25, at a temperature higher than the temperature at which the metal layer 25 is formed, for example. The temperature at which the metal layer 25 is formed is an example of a first temperature, and the temperature at which the metal layer 26 is formed is an example of a second temperature.

In the example illustrated in FIG. 8A, the electrode layer 6 includes an intermediate layer 6c formed between the barrier metal layer 6a and the electrode material layer 6b. The intermediate layer 6c is, for example, a tungsten silicon nitride film (WSiN film). The intermediate layer 6c is an example of a fourth layer.

When the electrode layer 6 illustrated in FIG. 8A is formed, for example, the barrier metal layer 6a, the metal layer 25, and the metal layer 26 are formed in sequence, and the barrier metal layer 6a, the metal layer 25, and the metal layer 26 are then heated at 650° C. to 900° C. (for example, 750° C. for 10 seconds). As a result, the intermediate layer 6c is formed between the barrier metal layer 6a and the metal layer 25.

According to the example illustrated in FIG. 8A, F atoms in the electrode material layer 6b can be prevented from diffusing into the block insulating film 5 by the intermediate layer 6c. The reason therefore is considered to be because Si atoms in the intermediate layer 6c function to barrier F atoms. According to the example illustrated in FIG. 8A, Si atoms in the metal layer 25 can also be prevented from diffusing into the block insulating film 5 by the intermediate layer 6c. The reason therefore is considered to be because Si—N bonds in the intermediate layer 6c function to prevent diffusion of Si atoms. Consequently, Si atoms can be prevented from damaging the insulating film 5b (block insulating film 5).

In the example illustrated in FIG. 8A, the thickness of the barrier metal layer 6a is, for example, 1.0 to 3.0 nm (preferably 1.5 to 2.0 nm). In addition, in the example illustrated in FIG. 8A, the thickness of the intermediate layer 6c is thinner than the thickness of the barrier metal layer 6a and is, for example, 0.1 to 0.5 times the thickness of the barrier metal layer 6a. Furthermore, in the example illustrated in FIG. 8A, the nitrogen concentration in the intermediate layer 6c is higher than the nitrogen concentration in the barrier metal layer 6a, and the silicon concentration in the intermediate layer 6c becomes high. The intermediate layer 6c may be an amorphous layer or may be a polycrystalline layer.

FIG. 8B illustrates an enlarged view of the electrode layer 6 in FIG. 8A, in which the thick lines in FIG. 8B represent the boundaries between the barrier metal layer 6a, the intermediate layer 6c, the metal layer 25, and the metal layer 26. The thin lines in FIG. 8B represent grain boundaries between crystal grains P1 in the barrier metal layer 6a and grain boundaries between crystal grains P2 in the metal layer 26.

In the example illustrated in FIG. 8A and FIG. 8B, the barrier metal layer 6a and the metal layer 26 are polycrystalline layers, and the metal layer 25 is an amorphous layer. When the metal layer 25 is formed at 300° C. or lower using the material gas and the reducing gas described above, the metal layer 25 can be formed as an amorphous layer. In this case, when the metal layer 26 is formed at a surface of the barrier metal layer 6a via the metal layer 25, crystallinity of the barrier metal layer 6a hardly affects crystallinity of the metal layer 26 by action of the metal layer 25. Consequently, the grain diameter of crystal grains P2 in the metal layer 26 can be increased even when the grain diameter of crystal grains P1 in the barrier metal layer 6a is small. As a result, electric resistance of the metal layer 26 (electrode layer 6) can be reduced. Furthermore, when the electrode layer 6 is formed from a WN film (barrier metal layer 6a) instead of a TiN film (barrier metal layer 6a′), electric resistance of the metal layer 25 (electrode layer 6) can be reduced. According to the example illustrated in FIG. 8A and FIG. 8B, the diameter of the crystal grains P2 in the metal layer 26 can be increased while preventing the problem associated with diffusion of B atoms.

The average grain diameter of the crystal grains P2 in the metal layer 26 is, for example, 50 nm or more. The thickness (length in the Z direction) of the metal layer 26 of the present embodiment is, for example, 25 nm or less than 25 nm. Therefore, according to the present embodiment, the average grain diameter of the crystal grains P2 in the metal layer 26 can be made twice or more the thickness of the metal layer 26. It is noted that the average grain diameter of the crystal grains P2 in the metal layer 26 will be described later in more detail.

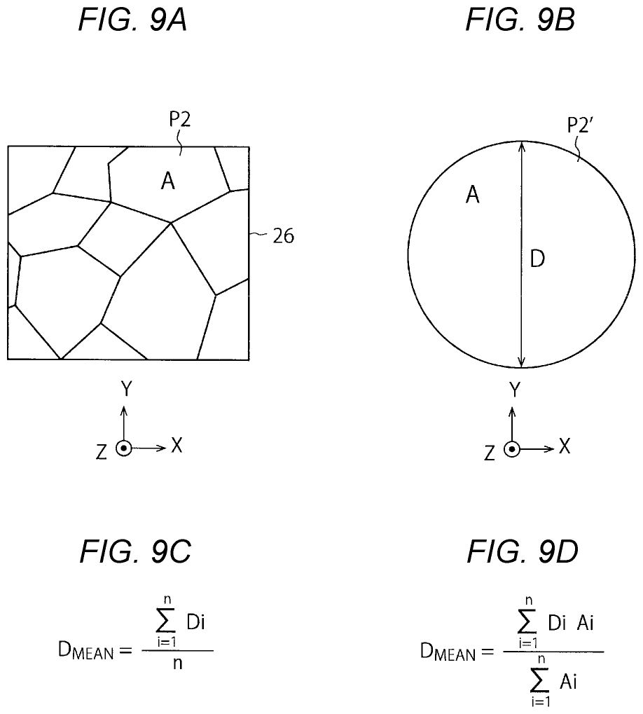

FIGS. 9A to 9D are diagrams illustrating a grain diameter of each crystal grain in a metal layer of the first embodiment.

FIG. 9A illustrates an example of an XY cross-section of the metal layer 26. The XY cross-section illustrated in FIG. 9A includes cross-sectional surfaces of multiple crystal grains P2 in the metal layer 26. FIG. 9A also illustrates an area A of a cross-sectional surface of a crystal grain P2 in the metal layer 26.

FIG. 9B illustrates a circle P2′ corresponding to this crystal grain P2. The area of the circle P2′ is regarded as equal to the area A of this crystal grain P2. FIG. 9B also illustrates the diameter D of the circle P2′. The relation between the area A and the diameter D satisfies the equation A=π(D/2)². In the present embodiment, the grain diameter of this crystal grain P2 is considered to be represented by the diameter D of the circle P2′. Accordingly, the grain diameter of the crystal grain P2 having the area A is calculated as D (=(4A/π)^{1/2}).

FIG. 9C represents a frequency average as an example of the average grain diameter D_{MEAN} of the multiple crystal grains P2 in the metal layer 26. When n crystal grains P2 are contained in a certain XY cross-section of the metal layer 26, the average grain diameter D_{MEAN} as a frequency average of these crystal grains P2 is calculated as D_{MEAN}=(ΣDᵢ)/n. Provided that, Dᵢ represents the grain diameter D of i^{th} crystal grain P2, and ΣDᵢ represents the sum of grain diameters D of first to n^{th} crystal grains P2. In addition, n represents an integer of 2 or more, and i represents an integer satisfying 1≤i≤n.

FIG. 9D represents a weighted average as an example of the average grain diameter D_{MEAN} of the multiple crystal grains P2 in the metal layer 26. When n crystal grains P2 are contained in a certain XY cross-section of the metal layer 26, the average grain diameter D_{MEAN} as a weighted average of these crystal grains P2 is calculated as D_{MEAN}=(ΣDᵢAᵢ)/(ΣAᵢ). Provided that, Aᵢ represents the area A of i^{th} crystal grain P2, and ΣAᵢ represents the sum of areas A of first to n^{th} crystal grains P2. In addition, ΣDᵢAᵢ represents the sum of values DA of first to n^{th} crystal grains P2.

In the present embodiment, the average grain diameter D_{MEAN} of the multiple crystal grains P2 in the metal layer 26 is represented by a weighted average. As described above, the average grain diameter D_{MEAN} (weighted average) of crystal grains P2 in the metal layer 26 is, for example, 50 nm or more. The thickness of the metal layer 26 of the present embodiment is, for example, 25 nm or less than 25 nm. Therefore, according to the present embodiment, the average grain diameter D_{MEAN} (weighted average) of the crystal grains P2 in the metal layer 26 can be made twice or more the thickness of the metal layer 26.

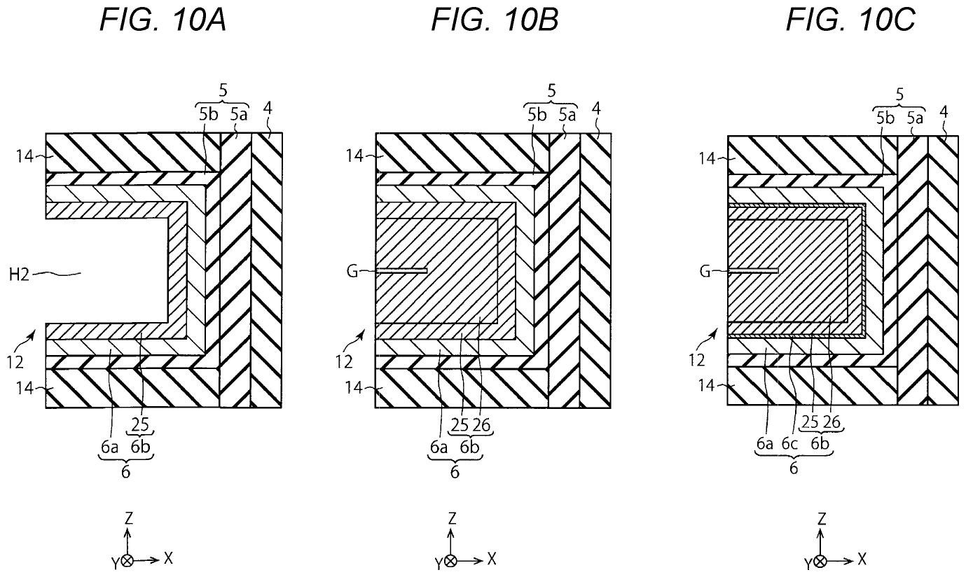

FIGS. 10A to 10C are cross-sectional views illustrating the details of the method for manufacturing the semiconductor device according to the first embodiment. More specifically, FIGS. 10A to 10C illustrate the method for manufacturing the semiconductor device illustrated in FIG. 8A.

When the electrode layer 6 is formed in each recess H2, the barrier metal layer 6a is firstly formed at a surface of the insulating film 5b (FIG. 10A). The barrier metal layer 6a is, for example, a WN film and is formed using WF₆ gas and NH₃ gas.

Thereafter, the metal layer 25 is formed at a surface of the barrier metal layer 6a (FIG. 10B). The metal layer 25 is, for example, a W layer and is formed using WF₆ gas and SiH₄ (or Si₂H₆) gas. The metal layer 25 of the present embodiment is formed, for example, at 300° C. or lower (preferably 200° C. or lower) as an amorphous layer. The metal layer 25 of the present embodiment is formed as an initial film of the electrode material layer 6b.

Thereafter, the metal layer 26 is formed at a surface of the metal layer 25 (FIG. 10B). The metal layer 26 is, for example, a W layer and is formed using WF₆ gas and H₂ gas. The metal layer 26 is formed as a polycrystalline layer in the step of FIG. 10B. The metal layer 26 of the present embodiment is formed at a temperature higher than the temperature at which the metal layer 25 is formed and is formed, for example, at 450° C. as a polycrystalline layer. The metal layer 25 may also be changed from an amorphous layer to a polycrystalline layer during formation of the metal layer 26 or after formation of the metal layer 26. In this case, the metal layer 25 is crystallized by annealing, for example, at 600° C. or higher and preferably 750° C. or higher and is changed from an amorphous layer to a polycrystalline layer. The metal layer 26 of the present embodiment forms the electrode material layer 6b together with the metal layer 25. The metal layer 26 of the present embodiment may be formed so as to include an air gap G.

The barrier metal layer 6a of the present embodiment is, for example, a WN film as described above. In this case, the barrier metal layer 6a, the metal layer 25, and the metal layer 26 may be heated at high temperature after forming the metal layer 26. Consequently, the intermediate layer 6c is formed between the barrier metal layer 6a and the metal layer 25 as illustrated in FIG. 10C. The intermediate layer 6c is formed by heating, at 650° C. to 900° C., the barrier metal layer 6a, the metal layer 25, and the metal layer 26, for example. At this time, the metal layer 25 may be changed from an amorphous layer to a polycrystalline layer as described above.

The barrier metal layer 6a of the present embodiment includes F atoms as impurity atoms when the barrier metal layer 6a is formed using WF₆ gas and NH₃ gas. The F atom concentration in the barrier metal layer 6a is, for example, 1.0×10²⁰ to 5.0×10²¹ atoms/cm³. Alternatively, the barrier metal layer 6a may be formed using WOCl₄ gas and NH₃ gas (O represents oxygen, and Cl represents chlorine). In this case, the barrier metal layer 6a includes Cl atoms as impurity atoms. The Cl atom concentration in the barrier metal layer 6a is, for example, 1.0×10²¹ to 5.0×10²² atoms/cm³. The barrier metal layer 6a may be formed using a gas including a F atom other than WF₆ gas and may be formed using a gas including a Cl atom other than WOCl₄ gas. According to the present embodiment, the problem associated with diffusion of F atoms can be avoided by forming the barrier metal layer 6a using a gas including a Cl atom instead of a gas including a F atom.

The step of forming the barrier metal layer 6a is shifted to the step of forming the metal layer 25 ex-situ, for example. The step of forming the metal layer 25 is shifted to the step of forming the metal layer 26 in-situ, for example.

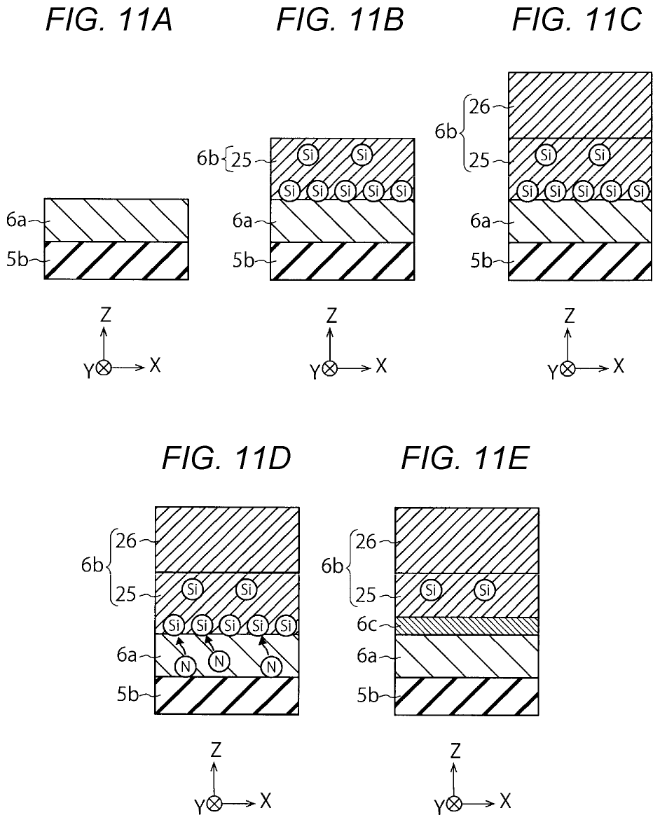

FIGS. 11A to 11E are cross-sectional views illustrating the details of a method for forming an electrode layer of the first embodiment. More specifically, FIGS. 11A to 11E illustrate a method for forming the electrode layer 6 illustrated in FIG. 8A.

FIG. 11A illustrates a step of forming the barrier metal layer 6a (WN film) at a surface of the insulating film 5b (Al₂O₃ film). FIG. 11B illustrates a step of forming the metal layer 25 (W layer) at a surface of the barrier metal layer 6a. FIG. 11B also illustrates Si atoms contained as impurity atoms in the metal layer 25. FIG. 11C illustrates a step of forming the metal layer 26 (W layer) at a surface of the metal layer 25.

FIG. 11D illustrates a step of heating the barrier metal layer 6a, the metal layer 25, and the metal layer 26 at high temperature after forming the metal layer 26. The barrier metal layer 6a, the metal layer 25, and the metal layer 26 are heated, for example, at 650° C. to 900° C. As a result, Si atoms in the metal layer 25 and N atoms in the barrier metal layer 6a react (FIG. 11D), and the intermediate layer 6c (WSiN film) is formed between the metal layer 25 and the barrier metal layer 6a (FIG. 11E).

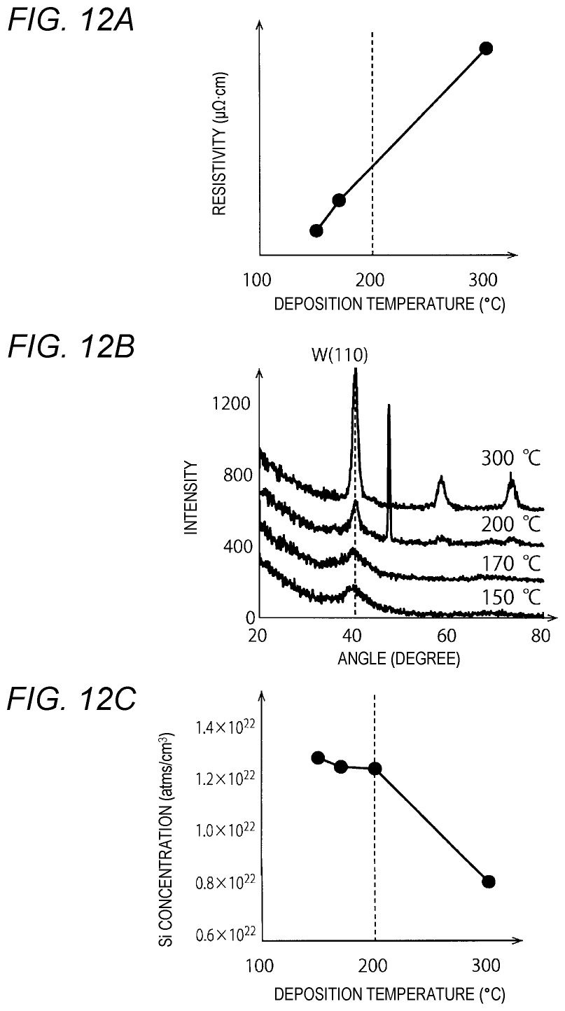

FIGS. 12A to 12C are graphs relating to characteristics of the semiconductor device according to the first embodiment.

FIG. 12A shows resistivity of the electrode material layer 6b (metal layers 25, 26). The horizontal axis in FIG. 12A represents temperature (deposition temperature) in forming the metal layer 25 by chemical vapor deposition (CVD). The vertical axis in FIG. 12A represents resistivity of the electrode material layer 6b in a manufactured semiconductor device. It is clear from FIG. 12A, the resistivity of the electrode material layer 6b is greatly increased as the deposition temperature increases in the case where the deposition temperature is 200° C. to 300° C. Accordingly, the deposition temperature is set to be, for example, 300° C. or lower and preferably 200° C. or lower in the present embodiment.

FIG. 12B shows intensity of scattered X-rays obtained when the metal layer 25 is irradiated with X-rays immediately after formation of the metal layer 25. Specifically, FIG. 12B shows intensity of X-rays scattered from the metal layer 25 in the direction range from 20 degrees to 80 degrees in the cases where the deposition temperature is 150° C., 170° C., 200° C., and 300° C. According to FIG. 12B, a high peak appears in the intensity of scattered X-rays when the deposition temperature is 300° C. This graph indicates that the metal layer 25 changes from an amorphous layer to a polycrystalline layer at the deposition temperature around 300° C.

FIG. 12C shows the Si concentration in the metal layer 25. The horizontal axis in FIG. 12C represents temperature (deposition temperature) in forming the metal layer 25 by CVD. The vertical axis in FIG. 12C represents the Si concentration in the metal layer 25 in the manufactured semiconductor device. It is clear from FIG. 12C, the Si concentration in the metal layer 25 increases as the deposition temperature decreases, and the deposition temperature is saturated around 200° C.

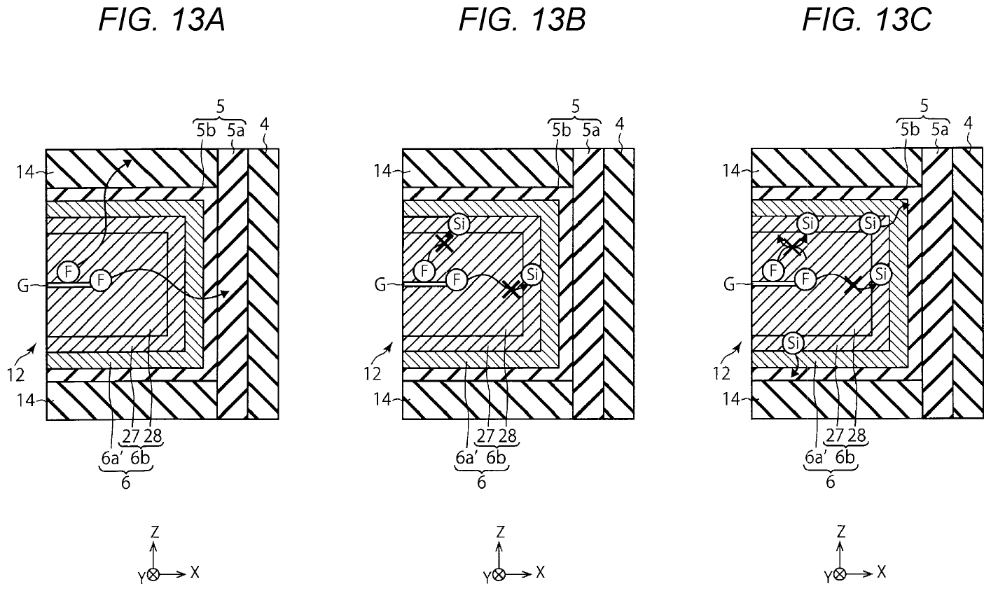

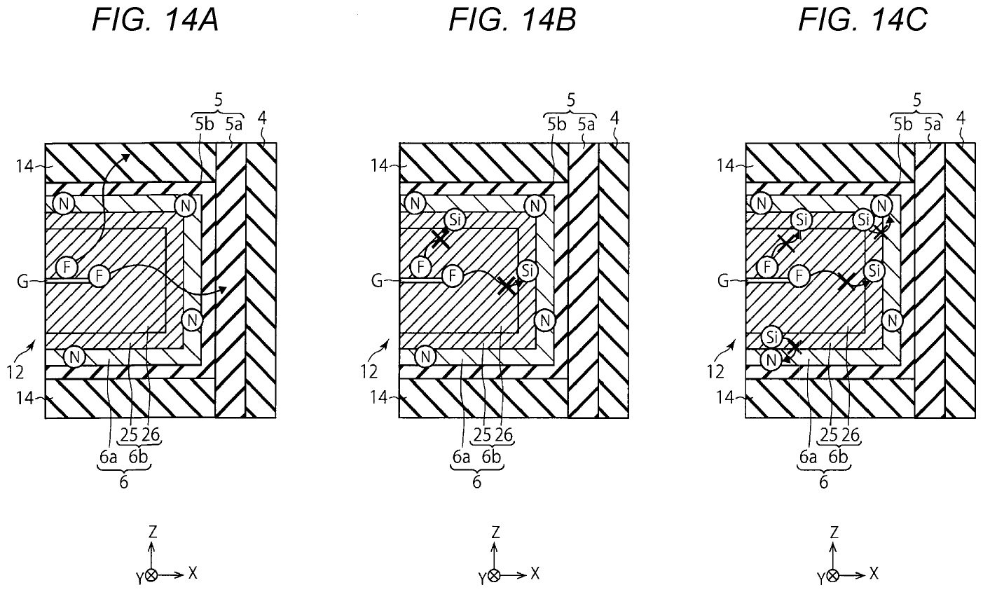

Then, the first embodiment and a second comparative example thereof will be compared with reference to FIG. 13A to FIG. 14C.

FIGS. 13A to 13C are cross-sectional views illustrating structures of a semiconductor device according to a second comparative example of the first embodiment.

The electrode layer 6 illustrated in FIG. 13A includes a barrier metal layer 6a′, a metal layer 27, and a metal layer 28. The barrier metal layer 6a′ is, for example, a TiN film and is formed using TiCl₄ gas and NH₃ gas. The metal layer 27 is, for example, a W layer and is formed using WF₆ gas and SiH₄ (or Si₂H₆) gas. The metal layer 28 is, for example, a W layer and is formed using WF₆ gas and H₂ gas. The same is true of the electrode layer 6 illustrated in FIG. 13B and the electrode layer 6 illustrated in FIG. 13C.

FIG. 13A illustrates, for example, the metal layer 27 in which the Si concentration in the metal layer 27 is lower than 6.0×10²¹ atoms/cm³. In this case, when F atoms derived from WF₆ gas are generated during formation of the metal layer 28, F atoms may diffuse into the block insulating film 5. As a result, the block insulating film 5 may be damaged by F atoms.

FIG. 13B illustrates, for example, the metal layer 27 in which the Si concentration in the metal layer 27 is 6.0×10²¹ to 1.5×10²² atoms/cm³. In this case, the F atoms react with Si atoms in the metal layer 27 to facilitate formation of Si—F bonds. Consequently, diffusion of F atoms into the block insulating film 5 can be prevented.

FIG. 13C illustrates, for example, the metal layer 27 in which the Si concentration in the metal layer 27 is higher than 1.5×10²² atoms/cm³. Diffusion of F atoms into the block insulating film 5 can be prevented also in this case. However, since the metal layer 27 includes many Si atoms, Si atoms in the metal layer 27 easily diffuse into the block insulating film 5. As a result, the block insulating film 5 may be damaged by Si atoms.

Therefore, the Si concentration in the metal layer 27 is desirably not too high and not too low. Consequently, the Si concentration in the metal layer 27 is desirably 6.0×10²¹ to 1.5×10²² atoms/cm³. However, since the electrode layer 6 of the present comparative example includes a TiN film as the barrier metal layer 6a′, the metal layer 27, which is a high-resistivity layer, is thickened, and electric resistance of the electrode layer 6 is increased.

FIGS. 14A to 14C are cross-sectional views illustrating structures of the semiconductor device according to the first embodiment.

The electrode layer 6 illustrated in FIG. 14A includes the barrier metal layer 6a, the metal layer 25, and the metal layer 26. The barrier metal layer 6a is, for example, a WN film and is formed using WF₆ gas and NH₃ gas. The metal layer 25 is, for example, a W layer and is formed using WF₆ gas and SiH₄ (or Si₂H₆) gas. The metal layer 26 is, for example, a W layer and is formed using WF₆ gas and H₂ gas. The same is true of the electrode layer 6 illustrated in FIG. 14B and the electrode layer 6 illustrated in FIG. 14C. According to the present embodiment, the metal layer 25, which is a high-resistivity layer, can be thinned, and electric resistance of the electrode layer 6 can be reduced by forming the electrode layer 6 including a WN layer as the barrier metal layer 6a.

FIG. 14A illustrates, for example, the metal layer 25 in which the Si concentration in the metal layer 25 is lower than 6.0×10²¹ atoms/cm³. In this case, when F atoms derived from WF₆ gas are generated during formation of the metal layer 26, F atoms may diffuse into the block insulating film 5. As a result, the block insulating film 5 may be damaged by F atoms. This is the same as in the case of FIG. 13A.

FIG. 14B illustrates, for example, the metal layer 25 in which the Si concentration in the metal layer 25 is 6.0×10²¹ to 1.5×10²² atoms/cm³. In this case, the F atoms react with Si atoms in the metal layer 25 to facilitate formation of Si—F bonds. Consequently, diffusion of F atoms into the block insulating film 5 can be prevented. This is the same as in the case of FIG. 13B.

FIG. 14C illustrates, for example, the metal layer 25 in which the Si concentration in the metal layer 25 is higher than 1.5×10²² atoms/cm³. Diffusion of F atoms into the block insulating film 5 can be prevented also in this case. However, since the metal layer 25 includes many Si atoms, Si atoms in the metal layer 25 easily diffuse into the block insulating film 5. As a result, the block insulating film 5 may be damaged by Si atoms. This is the same as in the case of FIG. 13C.

Therefore, the Si concentration in the metal layer 25 is desirably not too high and not too low. Consequently, the Si concentration in the metal layer 25 of the present embodiment is desirably 6.0×10²¹ to 1.5×10²² atoms/cm³.

According to the present embodiment, diffusion of Si atoms in the metal layer 25 into the block insulating film 5 can be prevented by action of N atoms in the barrier metal layer 6a. Therefore, when such action is sufficiently effective, the Si concentration in the metal layer 25 may be higher than 1.5×10²² atoms/cm³.

In addition, the electrode layer 6 illustrated in each of FIGS. 14A to 14C may include an intermediate layer 6c (WSiN film) between the barrier metal layer 6a and the electrode material layer 6b. Consequently, diffusion of Si atoms in the metal layer 25 and of F atoms in the electrode material layer 6b into the block insulating film 5 can be prevented by action of the intermediate layer 6c. Therefore, when such action is sufficiently effective, the Si concentration in the metal layer 25 may be lower than 6.0×10²¹ atoms/cm³ or higher than 1.5×10²² atoms/cm³.

As described above, the electrode layer 6 of the present embodiment is formed by the barrier metal layer 6a, the metal layer 23 (or 25), and the metal layer 24 (or 26). Thus, according to the present embodiment, an electrode layer 6 having preferable characteristics can be formed.

For example, when the barrier metal layer 6a is a WN film, electric resistance of the electrode layer 6 can be reduced by thinning the metal layer 23 (or 25), making it possible to prevent diffusion of F atoms. Electric resistance of the electrode layer 6 can be reduced by increasing the grain diameter of crystal grains in the metal layer 26. Increase in leak current due to the electrode layer 6 can be prevented by forming the metal layer 25 without using boron-containing gas. F atoms and Si atoms in the electrode layer 6 can be prevented from damaging the block insulating film 5 by making the Si concentration in the metal layer 25 6.0×10²¹ to 1.5×10²² atoms/cm³. Diffusion of F atoms and Si atoms can be prevented by forming the intermediate layer 6c between the barrier metal layer 6a and the electrode material layer 6b.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a film stack including a plurality of electrode layers and a plurality of first insulating films alternately stacked on top of one another;
a charge storage layer provided between a side face of the electrode layers through a second insulating film; and
a semiconductor layer provided between a side face of the charge storage layer through a third insulating film, wherein
at least one of the plurality of electrode layers includes a first layer and a second layer,
the first layer is a polycrystalline layer including tungsten and nitrogen, and
the second layer is an amorphous layer including tungsten.

2. The semiconductor device according to claim 1, wherein
the first layer further includes fluorine or chlorine.

3. The semiconductor device according to claim 1, wherein
the second layer further includes boron or silicon.

4. The semiconductor device according to claim 1, wherein
a silicon concentration in the second layer is between about 6.0×10²¹ and about 1.5×10²² atoms/cm³.

5. The semiconductor device according to claim 1, wherein
a silicon concentration in the second layer is higher than a boron concentration in the second layer.

6. The semiconductor device according to claim 1, wherein
the at least one electrode layer further includes a third layer,
the third layer is a polycrystalline layer including tungsten, and
the second layer is provided between the first layer and the third layer.

7. The semiconductor device according to claim 1, wherein
the at least one electrode layer further includes a fourth layer including tungsten, silicon, and nitrogen, and
the fourth layer is provided between the first layer and the second layer.

8. The semiconductor device according to claim 7, wherein
a nitrogen concentration in the fourth layer is higher than a nitrogen concentration in the first layer.

9. The semiconductor device according to claim 7, wherein
a thickness of the fourth layer is thinner than a thickness of the first layer.

10. A semiconductor device comprising:
a film stack including a plurality of electrode layers and a plurality of first insulating films alternately stacked on top of one another;
a charge storage layer provided between a side face of the electrode layers through a second insulating film; and
a semiconductor layer provided between a side face of the charge storage layer through a third insulating film, wherein
at least one of the plurality of electrode layers includes a first layer, a second layer, and a third layer,
the first layer includes tungsten and nitrogen,
the second layer includes tungsten,
the third layer includes multiple crystal grains having an average grain diameter equal to or larger than about 50 nanometers (nm), and
the second layer is provided between the first layer and the third layer.

11. The semiconductor device according to claim 10, wherein
the second layer is an amorphous layer including tungsten and silicon or a polycrystalline layer including tungsten and silicon.

12. The semiconductor device according to claim 10, wherein
the third layer includes tungsten and is a polycrystalline layer including the multiple crystal grains having an average grain diameter equal to or larger than about 50 nm.

13. The semiconductor device according to claim 10, wherein
the average grain diameter of the multiple crystal grains in the third layer is twice a thickness of the third layer or more.

14. The semiconductor device according to claim 10, wherein
the at least one electrode layer further includes a fourth layer including tungsten, silicon, and nitrogen, and
the fourth layer is provided between the first layer and the second layer.

15. A semiconductor device manufacturing method, comprising:
forming a film stack including a plurality of fifth layers and m a plurality of first insulating films alternately stacked on top of one another;
forming a charge storage layer provided between a side face of the fifth layers through a second insulating film;
forming a semiconductor layer provided between a side face of the charge storage layer through a third insulating film;
removing the fifth layers to form multiple first recesses in the film stack; and
forming multiple electrode layers in the first recesses, wherein
at least one electrode layer of the electrode layers is formed to include a first layer and a second layer,
the first layer includes tungsten and nitrogen,
the second layer includes tungsten, and
the second layer is formed at a temperature less than or equal to about 300° C. using a gas including tungsten and a reducing gas including silicon.

16. The semiconductor device manufacturing method according to claim 15, wherein
the first layer is formed using a gas including tungsten and fluorine or a gas including tungsten and chlorine.

17. The semiconductor device manufacturing method according to claim 15, wherein
the reducing gas further includes hydrogen.

18. The semiconductor device manufacturing method according to claim 15, wherein
the at least one electrode layer is formed to further include a third layer including multiple crystal grains having an average grain diameter equal to or larger than about 50 nm.

19. The semiconductor device manufacturing method according to claim 18, wherein
the second layer is formed at a first temperature, and
the third layer is formed at a second temperature higher than the first temperature after forming the second layer.

20. The semiconductor device manufacturing method according to claim 15, wherein
the at least one electrode layer is formed to further include a fourth layer including tungsten, silicon, and nitrogen.
